(19) United States
(12) Patent Application Publication
(10) Pub. No.: US 2016/0299591 A1
(43) Pub. Date: Oct. 13, 2016

(54) COMPOSITION FOR TOUCH PANEL ELECTRODE LINE AND TOUCH PANEL INCLUDING ELECTRODE LINE FABRICATED USING THE SAME

(71) Applicant: SAMSUNG SDI CO., LTD., Yongin-si (KR)

(72) Inventors: Chang Won PARK, Suwon-si (KR); Ah Reum KOO, Suwon-si (KR); Hee In NAM, Suwon-si (KR); Yong Wan SHIN, Suwon-si (KR); Jae Joon SHIM, Suwon-si (KR); Woo Sung LEE, Suwon-si (KR); Chang Geon CHOI, Suwon-si (KR)

(21) Appl. No.: 15/068,677

(22) Filed: Mar. 14, 2016

(30) Foreign Application Priority Data
Apr. 8, 2015 (KR) 10-2015-0049887

(51) Int. Cl. G06F 3/041; G03F 7/40; G03F 7/20; G03F 7/32; G03F 7/00; G03F 7/16

(52) U.S. Cl. CPC G06F 3/041; G03F 7/0007; G03F 7/168; G03F 7/20; G03F 7/322; G03F 7/40; G06F 2203/04103

(57) ABSTRACT

A composition for touch panel electrode lines, a method of forming touch panel electrode lines, and a touch panel including electrode lines fabricated using the same. The composition for touch panel electrode lines includes a conductive powder, an organic binder, a photoinitiator, a photopolymerizable compound, and a solvent, wherein the conductive powder includes silver powder and ITO powder, and the ITO powder has an average particle diameter (D50) of about 1 nm to about 100 nm and a specific surface area (BET) of about 10 m²/g to about 50 m²/g.

### CROSS-REFERENCE TO RELATED APPLICATION

Korean Patent Application No. 10-2015-0049887, filed on Apr. 8, 2015, in the Korean Intellectual Property Office, and entitled: “Composition for Touch Panel Electrode Line and Touch Panel Including Electrode Line Fabricated Using the Same,” is incorporated by reference herein in its entirety.

### BACKGROUND

1. Field

Embodiments relate to a composition for touch panel electrode lines and a touch panel including electrode lines fabricated using the same.

2. Description of the Related Art

Examples of a touch panel used as an input device of a display include personal digital assistants or the like. A touch panel allows input of user-defined commands or graphic information by generating corresponding voltage or current signals at a portion thereof pressed by a pen or a finger. Such touch panels may be resistive touch panels, capacitive touch panels, surface acoustic wave touch panels, or infrared touch panels, based on sensor technology. Recently, resistive touch panels and capacitive touch panels, which are placed on a flat panel display, particularly a liquid crystal display, and employ an analog-type input mechanism, are widely used.

### SUMMARY

Embodiments are directed to a composition for touch panel electrode lines including a conductive powder, an organic binder, a photoinitiator, a photopolymerizable compound, and a solvent. The conductive powder includes a silver powder and an ITO powder. The ITO powder has an average particle diameter (D50) of about 1 nm to about 100 nm and a specific surface area (BET) of about 10 m²/g to about 50 m²/g.

The composition may include about 50 wt % to about 90 wt % of the silver powder, about 0.1 wt % to about 3 wt % of the ITO powder, about 1 wt % to about 20 wt % of the organic binder, about 0.1 wt % to about 10 wt % of the photoinitiator, about 1 wt % to about 20 wt % of the photopolymerizable compound, and the solvent.

The silver powder may have an average particle diameter (D50) of about 0.1 μm to about 10 μm.

The organic binder may include at least one of an acrylic polymer, a cellulose polymer, and a combination thereof.

The photoinitiator may include at least one selected from chloroacetophenone, diethoxy acetophenone (DEAP), hydroxy acetophenone, 1-phenyl-2-hydroxy-2-methyl propane-1-one (HMPP), 1-hydroxy cyclohexyl phenyl ketone (HCPK), α-amino acetophenone, benzoin ether, benzyl dimethyl ketal, benzophenone, thioxanthone, and 2-ethylanthraquinone (2-ETAQ).

The photopolymerizable compound may include at least one polyfunctional monomer or oligomer selected from ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane ethoxy triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, and 1,6-hexanediol dimethacrylate.

Embodiments are also directed to a method of fabricating touch panel electrode lines including forming a composition film by printing and drying the composition for electrode lines as described above, forming an electrode line pattern by exposing the composition film to light through a photomask and developing the exposed composition film, and curing the electrode line pattern through a heat treatment.

Printing the composition for electrode lines may be performed by screen-printing, gravure printing, or inkjet printing.

Printing the composition for electrode lines may include coating the composition for an electrode line onto a substrate to provide a coated composition having a thickness of about 10 μm to about 50 μm. Drying the composition for electrode lines includes drying the coated composition at about 80° C. to about 120° C. for about 5 to about 20 minutes.

Exposing the composition film to light may include placing a photomask on the composition film, followed by UV irradiation at an irradiance of about 5 mW to about 20 mW and at a radiant exposure of about 100 mJ to about 300 mJ.

Developing the exposed composition film may include treating the exposed composition film in an aqueous alkali solution.

The heat treatment may include heat treatment of the formed electrode line pattern at a temperature of about 200° C. or less for about 30 minutes to about 2 hours.

Embodiments are also directed to a touch panel including electrode lines fabricated using the composition for touch panel electrode lines. The electrode lines may have an increase rate of contact resistance after 120 hours in a constant temperature/humidity chamber at 85° C. and 85% RH of about 0.05% to about 1.3%.

### BRIEF DESCRIPTION OF THE DRAWINGS

Features will become apparent to those of skill in the art by describing in detail exemplary embodiments with reference to the attached drawings in which:

FIG. 1 illustrates a sectional view of a capacitive touch panel according to an embodiment.

FIG. 2 illustrates a schematic diagram of electrode lines that use silver powder alone as a conductive powder.

FIG. 3 illustrates a schematic diagram of electrode lines that use both silver powder and ITO powder as a conductive powder.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

In accordance with an aspect, a composition for touch panel electrode lines may include a conductive powder including silver powder and ITO powder, an organic binder, a photoinitiator, a photopolymerizable compound, and a solvent.

Now, each component of the composition for touch panel electrode lines will be described in more detail.

Conductive Powder

The composition for touch panel electrode lines may include a silver (Ag) powder (a1) and an indium tin oxide powder (hereinafter, “ITO powder”) (a2) as a conductive powder.

The particle size of the silver powder (a1) may be on a nanometer or micrometer scale. For example, the silver powder may have a particle size of dozens to several hundred nanometers, or several to dozens of micrometers. In some implementations, the silver powder may be a mixture of two or more types of silver powders having different particle sizes.

The silver powder may have a spherical, flake or amorphous shape.

For example, the silver powder may have an average particle diameter (D50) of about 0.1 μm to about 10 μm, or, for example, about 0.5 μm to about 5 μm. The average particle diameter (D50) may be measured using, for example, a Model 1064D particle size analyzer (CILAS Co., Ltd.) after dispersing the conductive powder in isopropyl alcohol (IPA) at 25° C. for 3 minutes via ultrasonication. Within this range of average particle diameter, the composition may provide low contact resistance and low line resistance.

The silver powder (a1) may be present in an amount of about 50% by weight (wt %) to about 90 wt % based on the total weight of the composition. Within this range, the silver powder may further reduce an increase in resistance and may allow the composition to be easily formed into a paste. For example, the silver powder (a1) may be present in an amount of about 70 wt % to about 90 wt % based on the total weight of the composition.

The ITO powder (a2) may be a fine powder of indium oxide and tin oxide in a specific weight ratio. The ITO powder may have a specific average particle diameter.

The ITO powder may have an average particle diameter (D50) of about 1 nm to about 100 nm. If the average particle diameter (D50) of the ITO powder is more than about 1 nm, contact reliability may be enhanced by the ITO powder. If the average particle diameter (D50) of the ITO powder is less than about 100 nm, an increase in contact resistance may be avoided. In some embodiments, the ITO powder may have an average particle diameter (D50) of about 5 nm, 10 nm, 20 nm, 30 nm, 40 nm, 50 nm, 60 nm, 70 nm, 80 nm, or 90 nm, as examples. The ITO powder may have a specific surface area (BET) of about 10 m²/g to about 50 m²/g. If the specific surface area (BET) of the ITO powder is more than about 10 m²/g, contact reliability may be enhanced by the ITO powder. If the specific surface area (BET) of the ITO powder is less than about 50 m²/g, an increase in contact resistance may be avoided. In some embodiments, the ITO powder may have a specific surface area (BET) of about 10 m²/g, 15 m²/g, 20 m²/g, 25 m²/g, 30 m²/g, 35 m²/g, 40 m²/g, 45 m²/g, or 50 m²/g, as examples. When the ITO powder has an average particle diameter (D50) and a specific surface area in the above ranges, the composition may increase the weather resistance of touch panel electrode lines, thereby enhancing contact reliability between the electrode lines and an ITO film.

In an embodiment, a weight ratio (a1:a2) of the silver (Ag) powder (a1) to the ITO powder (a2) in the conductive powder may be from 1:0.005 to 1:0.02, or, for example, may be 1:0.005, 1:0.006, 1:0.007, 1:0.008, 1:0.009, 1:0.01, 1:0.011, 1:0.012, 1:0.013, 1:0.014, 1:0.015, 1:0.016, 1:0.017, 1:0.018, 1:0.019, or 1:0.02. Within this range, the composition may provide increased weather resistance of electrode lines while further enhancing contact reliability between the electrode lines and an ITO film.

In an embodiment, the average particle diameter of the silver (Ag) powder may be greater than the average particle diameter of the ITO powder. In an embodiment, a particle diameter ratio (a1:a2) of the silver (Ag) powder (a1) to the ITO powder (a2) in the conductive powder may be from 1:1 to 1000:1, or, for example 1:1 to 100:1, or, for example, 40:1 to 80:1 or 50:1 to 70:1, or, for example, 51:1, 52:1, 53:1, 54:1, 55:1, 56:1, 57:1, 58:1, 59:1, 60:1, 61:1, 62:1, 63:1, 64:1, 65:1, 66:1, 67:1, 68:1, 69:1, 70:1, 71:1, 72:1, 73:1, 74:1, 75:1, 76:1, 77:1, 78:1, 79:1, or 80:1. Within this range, the composition may further enhance contact reliability between electrode lines and an ITO film.

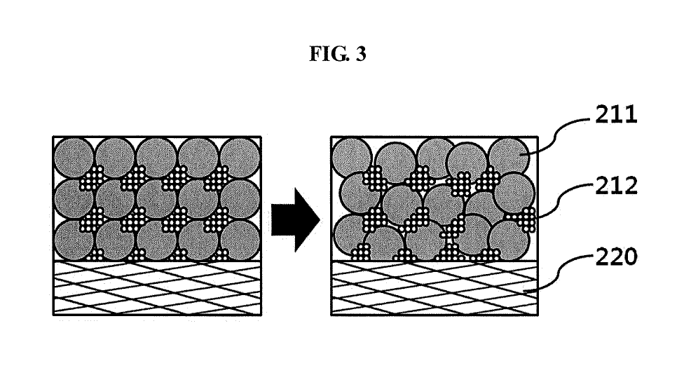

FIG. 2 illustrates a schematic sectional view of electrode lines fabricated using a composition for touch panel electrode lines that uses silver powder alone as a conductive powder, and FIG. 3 illustrates a schematic sectional view of electrode lines fabricated using a composition for touch panel electrode lines that uses both silver powder and ITO powder as a conductive powder, before and after weather resistance evaluation.

FIG. 2 illustrates an example wherein ITO powder is not used. In this example, after weather resistance evaluation, the contact area between silver particles or between silver particles and an ITO film may be reduced, thereby causing an increase in contact resistance. On the other hand, when a conductive powder includes ITO powder in addition to silver powder, as shown in FIG. 3, the ITO powder may be distributed between silver particles to enhance contact between silver particles and an ITO film, thereby improving contact reliability between electrode lines and the ITO film.

In an embodiment, the ITO powder (a2) may be present in an amount of about 0.1 wt % to about 3 wt % in the composition. Within this range, the composition may enhance contact reliability between electrode lines and an ITO film while allowing the realization of fine patterns.

Organic Binder

The organic binder may include acrylic polymers obtained by copolymerization of acrylic monomers having a hydrophilic group, such as a carboxyl group, for imparting alkali developability, and cellulose polymers such as ethyl cellulose, hydroxyethyl cellulose, hydroxypropyl cellulose, or hydroxyethyl hydroxypropyl cellulose. These may be used alone or in combination thereof.

The organic binder may be present in an amount of about 1 wt % to about 20 wt %, or, for example, about 4 wt % to about 15 wt % in the composition. If the content of the organic binder is more than about 1 wt %, the composition for touch panel electrode lines may have sufficient viscosity after being formed into paste or may provide sufficient adhesion to a glass substrate after being printed or dried. If the content of the organic binder is less than about 20 wt %, decomposition of the organic binder may be easily achieved during baking. An increase in resistance of the composition for touch panel electrode lines due to an excess of the binder may be reduced or avoided.

Photoinitiator

The photoinitiator may be a suitable photoinitiator that exhibits good photo-reactivity at a wavelength of about 200 nm to about 400 nm.

Examples of the photoinitiator may include chloroacetophenone, diethoxy acetophenone (DEAP), hydroxy acetophenone, 1-phenyl-2-hydroxy-2-methyl propane-1-one (HMPP), 1-hydroxy cyclohexyl phenyl ketone (HCPK), α-amino acetophenone, benzoin ether, benzyl dimethyl ketal, benzophenone, thioxanthone, 2-ethylanthraquinone (2-ETAQ), or the like. For example, commercially available photoinitiators include Darocure 1173, Irgacure-184, Irgacure-907, and Irgacure-651 (all from BASF). These may be used alone or in combination thereof.

For example, the photoinitiator may be present in an amount of about 0.1 wt % to about 10 wt % in the composition. Within this range, the composition for touch panel electrode lines may further enhance resolution of an electrode line pattern and may exhibit an improved curing degree, thereby further enhancing adhesion between electrode lines and a substrate.

Photopolymerizable Compound

The photopolymerizable compound may be a polyfunctional monomer or oligomer generally used in a photosensitive resin composition. The photopolymerizable compound may include, for example, at least one selected from of ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane ethoxy triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, and 1,6-hexanediol dimethacrylate.

The photopolymerizable compound may be present in an amount of about 1 wt % to about 20 wt % in the composition. Within this range of the photopolymerizable compound, the composition for touch panel electrode lines may exhibit further enhanced photocuring efficiency, thereby preventing detachment of patterns during developing. In addition, the polyfunctional monomer or oligomer may further reduce decomposition of organic matter during baking.

Solvent

The solvent may be a suitable solvent for use in a composition for electrode lines. For example, the solvent may have a boiling point of about 120° C. or higher. Examples of the solvent may include methyl cellosolve, ethyl cellosolve, butyl cellosolve, aliphatic alcohols, α-terpineol, β-terpineol, dihydro-terpineol, ethylene glycol, ethylene glycol mono butyl ether, butyl cellosolve acetate, and Texanol. These may be used alone or in combination thereof.

The solvent may be present in the balance amount. In some implementations, the solvent may be present in an amount of about 1 wt % to about 40 wt % in the composition to provide suitable viscosity adjustment.

In addition, the composition for touch panel electrode lines may further include additives such as plasticizers, dispersants, surfactants, and viscosity modifiers.

Another aspect relates to a method of fabricating electrode lines using the composition for electrode lines as set forth above. Electrode lines may be fabricated by a suitable method used in fabricating an electrode.

The method of fabricating touch panel electrode lines may include forming a composition film by printing and drying the composition for electrode lines, forming an electrode line pattern by exposing the composition film to light through a photomask and developing the exposed composition film, and curing the electrode line pattern through heat treatment.

For example, the method may include printing the composition for electrode lines onto a substrate and drying the composition, exposing the dried composition film to light, removing an exposed region or an unexposed region of the composition film by developing the composition film, and drying and baking a remaining portion of the composition film. In printing, the composition for electrode lines may be coated onto a substrate to a thickness of about 10 μm to about 50 μm. In drying, the coated composition may be dried at about 80° C. to about 120° C. for about 5 to about 20 minutes. In exposing, a photomask may be placed on the dried composition film, followed by UV irradiation at an irradiance of about 5 mW to about 20 mW and at a radiant exposure of about 100 mJ to about 300 mJ. In development, the composition film may be treated in an aqueous alkali solution. In baking, the remaining composition film (for example, the composition film remaining after developing the composition film) may be treated at a temperature of about 200° C. or less, or, for example, at about 130° C. to about 150° C. for about 30 minutes to about 2 hours.

In accordance with a further aspect, a touch panel may include electrode lines formed of the composition for electrode lines as set forth above.

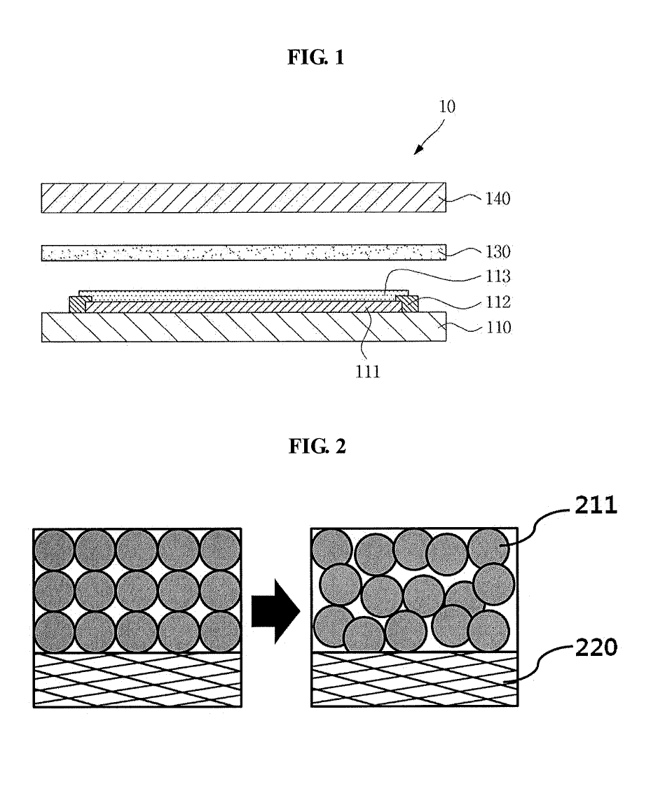

FIG. 1 illustrates a sectional view of a capacitive touch panel, as a touch panel according to one embodiment.

Referring to FIG. 1, a touch panel 10 according to this embodiment may include a transparent substrate 110, an electrode pattern 111 formed on the transparent substrate 110, an electrode line 112 connected to one end of the electrode pattern 111, and a barrier formed on the electrode pattern 111.

The transparent substrate 110 may provide a region where the electrode pattern 111, the electrode line 112, and the like are to be formed. The transparent substrate 110 may be formed of a material having specific strength. For example, the transparent substrate may be formed of polyethylene terephthalate (PET), polycarbonate (PC), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), polystyrene (PS), biaxially oriented polystyrene (K resin-containing biaxially oriented PS; BOPS), glass, or tempered glass. When the electrode pattern is formed on one surface of the transparent substrate 110, the one surface of the transparent substrate 110 may be subjected to high-frequency treatment or primer treatment to enhance adhesion between the transparent substrate 110 and the electrode pattern.

The electrode pattern 111 may be formed on the transparent substrate 110. The electrode pattern 111 may have electrical conductivity, and may serve to detect a change in capacitance caused by a user's touch to allow a controller to recognize a touch coordinate. The electrode pattern 111 may include, for example, an ITO transparent electrode.

The barrier layer 113 may be formed between the electrode pattern and an adhesive layer 130. The barrier layer 113 may prevent moisture from penetrating the electrode pattern 111.

The adhesive layer 130 may bond components of the capacitive touch panel 10 to each other. The adhesive layer 130 may be formed between a window substrate 140 and the barrier layer 113. The adhesive layer 130 may be formed of, for example, a transparent material, so as not to hinder a user from recognizing an output image. For example, the adhesive layer may be formed of an optically clear adhesive (OCA). The window substrate 140 may be bonded to an upper side of the adhesive layer 130. The window substrate 140 may be located at the outermost side of the touch panel 10 to receive a user's touch input. The window substrate 140 may be formed of tempered glass to serve as a protective layer.

The electrode pattern 111 may be formed with the electrode line 112 at one end thereof to receive electric signals from the electrode pattern 111. The electrode line 112 may be formed of the composition for touch panel electrode lines by screen-printing, gravure printing, inkjet printing, or the like.

In one embodiment, the electrode line may have an increase rate (%) of contact resistance after 48 hours of about 0.05% to about 1.2%, for example, about 0.1%, 0.2%, 0.3%, 0.4%, 0.5%, 0.6%, 0.7%, 0.8%, 0.9%, 1.0%, 1.1%, or 1.2%, as calculated according to Equation 1:

Increase rate of contact resistance after 48 hr (%)={(R2−R1/R1}×100

In one embodiment, the electrode line may have an increase rate (%) of contact resistance after 120 hours of about 0.05% to about 1.3%, for example, about 0.1%, 0.2%, 0.3%, 0.4%, 0.5%, 0.6%, 0.7%, 0.8%, 0.9%, 1.0%, 1.1%, or 1.3%, as calculated according to Equation 2:

Increase rate of contact resistance after 120 hr (%)={(R3−R1)/R1}×100

In Equations 1 and 2, R1 is an initial contact resistance of an electrode line specimen; R2 is a contact resistance of the specimen as measured after leaving the specimen in a constant temperature/humidity chamber at 85° C. and 85% RH for 48 hours; and R3 is a contact resistance of the specimen as measured after leaving the specimen in a constant temperature/humidity chamber at 85° C. and 85% RH for 120 hours.

### EXAMPLES

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Details of the components used in Examples and Comparative Examples are as follows:

(A) Conductive Powder

(a1) Silver powder: 4-8F (average particle diameter (D50): 1.8 μm, Dowa Electronics Materials)

(a2-1) ITO powder: ITO Powder (Yellow) (average particle diameter (D50): 30 nm, specific surface area: 30 m²/g, Advanced Nano Products Co., Ltd.)

(a2-2) ITO powder: 71099 (average particle diameter (D50): 300 nm, specific surface area: 3 m²/g, Indium Corporation)

(B) Organic binder: JM026 (Methacrylic acid/2,2,4-trimethyl-1,3-pentanediol monoisobutyrate copolymer (w/w=3:7), SOLTECH Co., Ltd.)

(C) Photoinitiator: IC907 (Ciba Specialty Chemicals)

(D) Photopolymerizable compound: TMPEOTA (Trimethylolpropane(EO)3 Triacrylate, SOLTECH Co., Ltd.)

(E) Solvent: Texanol (SOLTECH Co., Ltd.)

(F) Additive: BYK3700 (BYK Chemie)

### Examples 1 to 3 and Comparative Examples 1 to 2

The above components were weighed as listed in Table 1 and sufficiently dispersed using a three-roll mill, thereby preparing compositions for touch panel electrode lines. The prepared compositions were evaluated as to the following properties. Results are shown in Table 1.

Property Evaluation

(1) Resolution of line pattern (μm): As used herein, resolution of a line pattern refers to a minimum achievable linewidth of an electrode line. The resolution of a line pattern was measured on a line pattern specimen prepared by printing the composition for touch panel electrode lines.

Each of the compositions for touch panel electrode lines prepared in Examples 1 to 3 and Comparative Examples 1 to 2 was screen printed onto a PET film, dried in an oven at 100° C. for 10 minutes and exposed to UV light through a photomask, followed by alkaline development and curing in an oven 145° C. for 40 minutes, thereby preparing a line pattern specimen made up of 10 electrode lines having linewidths increasing from 10 μm to 100 μm by 10 μm arranged at constant intervals.

For the prepared line pattern specimen, the shape of each electrode line of a line pattern was observed using an optical microscope. Among electrode lines having no disconnection, the linewidth of an electrode line having a minimum linewidth was defined as a resolution value (μm).

(2) Contact resistance: Each of the compositions for touch panel electrode lines prepared in Examples 1 to 3 and Comparative Examples 1 to 2 was screen-printed onto a PET film, dried in an oven at 100° C. for 10 minutes and exposed to UV light through a photomask, followed by alkaline development and curing in an oven 145° C. for 40 minutes, thereby preparing a line pattern specimen made up of 10 electrode lines having linewidths increasing from 10 μm to 100 μm by 10 μm arranged at constant intervals.

For the prepared line pattern specimen, the initial contact resistance was measured. Then, the specimen was placed in a constant temperature/humidity chamber at 85° C. and 85% RH, followed by measuring contact resistance after 48 hours and 120 hours, thereby calculating increase rates of contact resistance according to Equations 1 and 2:

Increase rate of contact resistance after 48 hr (%)={(R2−R1/R1}×100 <Equation 1>

Increase rate of contact resistance after 120 hr (%)={(R3−R1)/R1}×100 <Equation 2>

where R1 is an initial contact resistance of the specimen; R2 is a contact resistance of the specimen as measured after leaving the specimen in a constant temperature/humidity chamber at 85° C. and 85% RH for 48 hours; and R3 is a contact resistance of the specimen as measured after leaving the specimen in a constant temperature/humidity chamber at 85° C. and 85% RH for 120 hours.

TABLE 1

| (Unit: | Example | Example | Example | Comparative | Comparative |
|---|---|---|---|---|---|
| wt %) | 1 | 2 | 3 | Example 1 | Example 2 |
| (a1) | 75 | 75 | 75 | 75 | 75 |
| (a2-1) | 1 | 0.5 | 1.5 | — | — |
| (a2-2) | — | — | — | — | 1 |
| (B) | 10 | 10 | 10 | 10 | 10 |
| (C) | 1 | 1 | 1 | 1 | 1 |
| (D) | 3 | 3 | 3 | 3 | 3 |
| (E) | 8 | 8.5 | 7.5 | 9 | 8 |
| (F) | 2 | 2 | 2 | 2 | 2 |
| Pattern | 20 | 20 | 30 | 20 | 20 |
| resolution (μm) | | | | | |
| Increase rate of | 1.01 | 1.13 | 1.01 | 1.49 | 1.26 |
| contact | | | | | |
| resistance after | | | | | |
| 48 hr (%) | | | | | |
| Increase rate of | 1.07 | 1.24 | 1.05 | 5.78 | 2.08 |
| contact | | | | | |
| resistance after | | | | | |
| 120 hr (%) | | | | | |

As shown in Table 1, line pattern specimens according to Examples 1, 2, and 3, each including ITO powder having an average particle diameter within the range of 1 nm to about 100 nm and a specific surface area (BET) within the range of about 10 m²/g to about 50 m²/g exhibited a much lower increase rate of contact resistance after 48 hours and after 120 hours, as compared to Comparative Example 1, which lacked an ITO powder, and as compared to Comparative Example 2, in which the ITO powder did not have an average particle diameter within the range of 1 nm to about 100 nm and a specific surface area (BET) within the range of about 10 m²/g to about 50 m²/g.

By way of summation and review, touch panel products have traditionally been developed with a focus on functionality. Accordingly, research on a bezel portion, which corresponds to a non-display region of a panel or a display, has not been actively conducted. Thus, such a touch panel generally has had a large bezel width. (Here, the term “bezel” refers to a periphery of a display, which is a non-display region where no image is to be output.)

Recently, with the diversification of functions of displays, display development has focused on increasing the size of a display region where images are to be output. Particularly, the design of a display has been developed with a view toward reducing the bezel width to increase the size of the display region while maintaining the overall size of the display.

In order to reduce the bezel width, the width of electrode lines or distances between the electrode lines may be reduced. However, reduction in width of the electrode lines may cause increase in resistance and reduction in touch sensitivity. In addition, there may be a limit to the extent to which the width of the electrode lines may be reduced. Further, touch sensitivity may deteriorate due to noise generated between the electrode lines with decreasing distances between the electrode lines.

Accordingly, as an electrode line pattern is miniaturized and the contact area between the electrode lines and an ITO film is reduced, an improvement in contact resistance characteristics of the electrode lines is desirable.

Embodiments provide a composition for touch panel electrode lines that has good weather resistance and low contact resistance.

Embodiments further provide a composition for touch panel electrode lines that has good printability and allows for the formation of fine patterns, thereby realizing high resolution.

Embodiments further provide a touch panel including electrode lines fabricated using the composition for touch panel electrode lines.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A composition for touch panel electrode lines, the composition comprising:
a conductive powder, an organic binder, a photoinitiator, a photopolymerizable compound, and a solvent,
wherein the conductive powder includes a silver powder and an ITO powder, and
the ITO powder has an average particle diameter (D50) of about 1 nm to about 100 nm and a specific surface area (BET) of about 10 m²/g to about 50 m²/g.

2. The composition as claimed in claim 1, including:
about 50 wt % to about 90 wt % of the silver powder;
about 0.1 wt % to about 3 wt % of the ITO powder;
about 1 wt % to about 20 wt % of the organic binder;
about 0.1 wt % to about 10 wt % of the photo initiator;
about 1 wt % to about 20 wt % of the photopolymerizable compound; and
the solvent.

3. The composition as claimed in claim 1, wherein the silver powder has an average particle diameter (D50) of about 0.1 μm to about 10 μm.

4. The composition as claimed in claim 1, wherein the organic binder includes at least one of an acrylic polymer, a cellulose polymer, and a combination thereof.

5. The composition for touch panel electrode lines as claimed in claim 1, wherein the photoinitiator includes at least one selected from chloroacetophenone, diethoxy acetophenone (DEAP), hydroxy acetophenone, 1-phenyl-2-hydroxy-2-methyl propane-1-one (HMPP), 1-hydroxy cyclohexyl phenyl ketone (HCPK), α-amino acetophenone, benzoin ether, benzyl dimethyl ketal, benzophenone, thioxanthone, and 2-ethylanthraquinone (2-ETAQ).

6. The composition as claimed in claim 1, wherein the photopolymerizable compound includes at least one polyfunctional monomer or oligomer selected from ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane ethoxy triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, and 1,6-hexanediol dimethacrylate.

7. A method of fabricating touch panel electrode lines, the method comprising:
forming a composition film by printing and drying the composition as claimed in claim 1;
forming an electrode line pattern by exposing the composition film to light and developing the exposed composition film; and
curing the electrode line pattern through a heat treatment.

8. The method as claimed in claim 7, wherein printing the composition for electrode lines is performed by screen-printing, gravure printing, or inkjet printing.

9. The method as claimed in claim 7, wherein:
printing the composition includes coating the composition onto a substrate to provide a coated composition having a thickness of about 10 μm to about 50 μm, and
drying the composition includes drying the coated composition at about 80° C. to about 120° C. for about 5 to about 20 minutes.

10. The method as claimed in claim 7, wherein exposing the composition film to light includes placing a photomask on the composition film, followed by UV irradiation at an irradiance of about 5 mW to about 20 mW and at a radiant exposure of about 100 mJ to about 300 mJ.

11. The method as claimed in claim 7, wherein developing the exposed composition film includes treating the exposed composition film in an aqueous alkali solution.

12. The method of fabricating touch panel electrode lines as claimed in claim 7, wherein the heat treatment includes heat treatment of the formed electrode line pattern at a temperature of about 200° C. or less for about 30 minutes to about 2 hours.

13. A touch panel including electrode lines fabricated using the composition as claimed in claim 1.

14. The touch panel as claimed in claim 13, wherein the electrode lines have an increase rate of contact resistance after 120 hours in a constant temperature/humidity chamber at 85° C. and 85% RH of about 0.05% to about 1.3%.
